(19) United States
(12) Patent Application Publication
(10) Pub. No.: US 2026/0059672 A1
(43) Pub. Date: Feb. 26, 2026

(54) AUTOMATION FIELD DEVICE

(71) Applicant: Endress+Hauser SE+Co. KG, Maulburg (DE)

(72) Inventors: Raphael Schonhardt, Rheinfelden (DE); Michael Lais, Schönau im Schwarzwald (DE); Vitogiuseppe Di Cosola, Hartheim (DE)

(21) Appl. No.: 19/103,861

(22) PCT Filed: Jul. 17, 2023
(86) PCT No.: PCT/EP2023/069790

§ 371 Date: Feb. 14, 2025

(30) Foreign Application Priority Data
Aug. 24, 2022 (DE) 10 2022 121 389.7

(51) Int. Cl. H05K 5/00; H05K 5/02

(52) U.S. Cl. CPC H05K 5/006; H05K 5/0056; H05K 5/0221

(57) ABSTRACT

A field device of automation technology includes: a field device housing; a field device electronics unit having at least one circuit board; a circuit board holder arranged in the housing for holding the circuit board, wherein the circuit board holder has an engagement mechanism for resistance fastening of the circuit board, wherein the circuit board has at least one counter-engagement mechanism corresponding to the engagement mechanism, wherein the engagement mechanism is a latch formed from the wall or provided in the wall, wherein the latch is flexibly embodied such that, in a non-engaged state, the latch extends out from the outer contour of the wall of the circuit board holder, and, in an engaged state, the latch has moved in the direction of the at least one circuit board as to be engaged with the counter-engagement mechanism.

The invention relates to a field device of automation technology as well as to a method for producing such a field device of automation technology.

Known from the state of the art are field devices, which are used in industrial plants. In process automation technology, as well as in manufacturing automation technology, field devices are often applied. Referred to as field devices are, in principle, all devices, which are applied near to a process and which deliver, or process, process relevant information. Field devices are used for registering and/or influencing process variables. Serving for registering process variables are measuring devices, or sensors. Such are used, for example, for pressure and temperature measurement, conductivity measurement, flow measurement, etc. and register the corresponding process variables, pressure, temperature, conductivity, pH value, fill level, flow, etc. Used for influencing process variables are actuators. Such are, for example, pumps or valves, which can influence the flow of a liquid in a tube or pipe or the fill level in a container. Besides the above mentioned measuring devices and actuators, referred to as field devices are also remote I/Os, radio adapters, and, in general, devices, which are arranged at the field level.

A large number of such field devices are manufactured and sold by the Endress+Hauser group of companies.

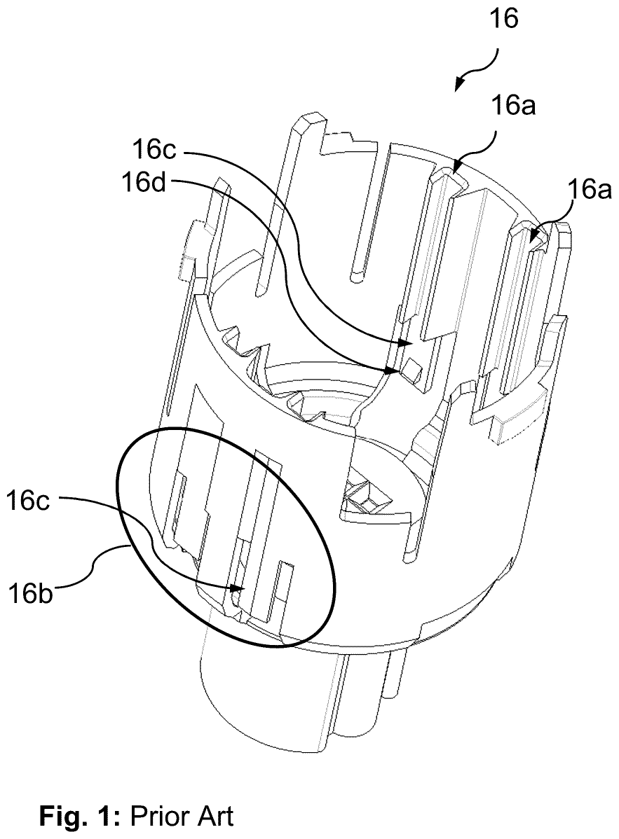

Such field devices have, especially, at least at times and/or at least sectionally in contact with a process medium, a sensor element, which serves for producing a signal dependent on the process variable. Furthermore, these devices have an electronics unit arranged in a housing, wherein the electronics unit serves for processing and/or forwarding signals, especially electrical and/or electronic signals, produced by the sensor unit. Typically, the electronics unit comprises a plurality of circuit boards with components arranged thereon. The circuit boards are usually arranged and mechanically secured in a circuit board holder. FIG. 1 shows such a circuit board holder, such as known in the state of the art. In the state of the art, it is presently usual for mechanical securement of the circuit boards to provide a releasable engagement or fixing mechanism located at the bottom of the circuit board holder for securing the circuit board to the circuit board holder. The arrangement of the engagement or fixing mechanism at the bottom of the circuit board holder is such that removal from a mold is possible. The engagement or fixing mechanism is usually implemented in such a manner that an elongated flexible arm extends from a side wall of the circuit board holder and has on a side toward the central axis of the circuit board holder a nose, which engages in a corresponding recess of the installed circuit board.

By embodiment and bottom-near arrangement of the engagement or fixing mechanism, the circuit board holder is penetrated at its outwardly facing side wall and is, thus, no longer sealed there. This lack of sealing means that in the case of potting processes, in the case of which the circuit boards mounted in the circuit board holder are poured over with a potting compound, e.g., silicone gel, it is not possible to do the pouring on the circuit board holder before introduction into the housing of the field device (preassembly of the circuit board holder), since the potting compound is not retained in the circuit board holder. For this reason, the circuit board holder needs first to be introduced in the housing, before the pouring, since then the housing can serve as outer mold for the circuit board holder, in order, thus, to prevent, at least partially, escape of the potting compound. In order to assure that the potting compound during its pouring on the circuit board holder installed in the housing does not leak into unintended regions of the housing, extra sealing measures are necessary in the housing and/or around the circuit board holder for the pouring. These additional measures lead, in turn, to increased costs and efforts for manufacturing. Furthermore, the potting compound requires more time for curing, the greater the amount of potting compound poured into the housing.

An object of the invention is, thus, to overcome these problems.

The object is achieved according to the invention by the field device of automation technology as defined in claim 1 and the method as defined in claim 8.

The automation field device of the invention comprises:
a field device housing;
arranged in the field device housing, a field device electronics unit having at least one circuit board;
arranged in the field device housing, a circuit board holder for holding the at least one circuit board, wherein the circuit board holder with a surrounding outer contour of a wall is fitted at least in a subregion to an inner contour of the field device housing in such a manner that the outer contour of the circuit board holder lies essentially flushly against the inner contour of the field device housing, wherein the circuit board holder has in the subregion at least one engagement mechanism for resistance capable securing of the at least one circuit board, wherein the at least one circuit board has at least one counter-engagement mechanism corresponding to the engagement mechanism of the circuit board holder, wherein the engagement mechanism is embodied in the form of a latch formed from the wall or provided in the wall, wherein the latch is flexibly embodied in such a manner that, in a non-engaged state, in the case of which the circuit board holder, at least with the subregion, is not completely installed in the field device housing, the latch extends out from the outer contour of the wall of the circuit board holder, and, in an engaged state, in the case of which the circuit board holder, at least with the subregion, is installed in the field device housing, the latch has moved in the direction of the at least one circuit board, in order thus to be engaged with the counter-engagement mechanism, wherein the at least one circuit board is installed in the circuit board holder and the circuit board holder, at least with the subregion, is installed in the field device housing, such that the engagement and the counter-engagement mechanism are engaged with one another and the circuit board holder holds the at least one circuit board, wherein the at least one circuit board is potted in the circuit board holder with a potting compound to a predetermined potting compound height, wherein the engagement and counter-engagement mechanisms are embodied in, or on, the circuit board holder and the at least one circuit board in such a manner that the engagement and counter-engagement mechanisms lie above the potting compound height, such that the engagement and counter-engagement mechanisms are not potted.

An advantageous embodiment of the automation field device of the invention can provide that the latch comprises an elongated arm prepared from the wall of the circuit board holder and an engagement catch located at an end of the elongated arm.

Another advantageous embodiment of the automation field device of the invention can provide that the at least one circuit board (15a) has at least one recess, in which the latch can engage in the engaged state.

In turn, another advantageous embodiment of the automation field device of the invention can provide that the circuit board holder has at least two engagement mechanisms for resistance capable securing of the at least one circuit board and the at least one circuit board has at least two counter-engagement mechanisms corresponding to the engagement mechanisms of the circuit board holder. Especially, the embodiment can provide that the at least two engagement mechanisms of the circuit board holder are arranged diametrally opposite one another and the at least two counter-engagement mechanisms of the at least one circuit board are formed diametrally opposite one another on a circuit board edge of the at least one circuit board, wherein the circuit board edge is located at a trailing end of the circuit board installed in the circuit board holder.

Another advantageous embodiment of the automation field device of the invention can provide that the circuit board holder has the form of a cup.

Another advantageous embodiment of the automation field device of the invention can provide that the circuit board holder is embodied in such a manner that it has no opening in its outer contour up to the predetermined potting compound height.

The invention relates further to a method for producing an automation field device according to at least one of the above described embodiments, comprising method steps as follows:
providing the field device housing;
providing the field device electronics unit with the at least one circuit board;
providing the circuit board holder for holding the at least one circuit board;
installing the at least one circuit board in the circuit board holder in the non-engaged state, in the case of which the circuit board holder, at least with the subregion, is not yet installed in the field device housing; and
installing the circuit board holder, at least with the subregion, in the field device housing, such that the latch moves in the direction of the at least one circuit board and engages the counter-engagement mechanism in the engaged state.

An advantageous form of embodiment of the method of the invention can provide that the at least one circuit board is potted in the circuit board holder with a potting compound to the predetermined potting compound height, before the circuit board holder is installed in the field device housing.

An alternative form of embodiment of the method of the invention can provide that the at least one circuit board is potted in the circuit board holder with a potting compound to the predetermined potting compound height, after the circuit board holder is installed in the field device housing.

The invention will now be explained in greater detail based on the appended drawing, the figures of which show as follows:

FIG. 1 a circuit board holder known in the state of the art, such as has usually been applied in a field device of automation technology;

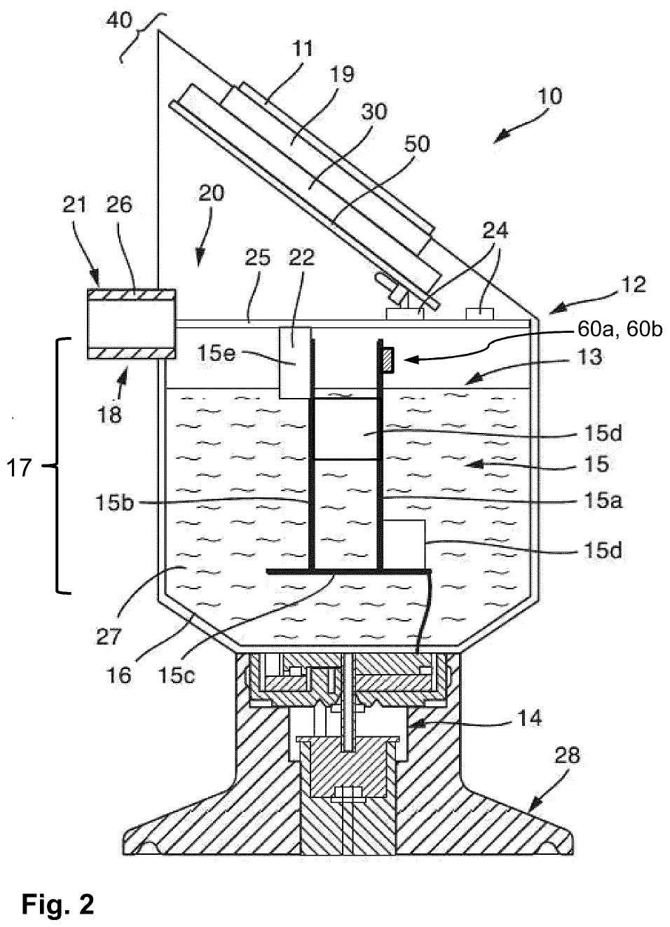

FIG. 2 by way of example, a sectional view of a field device of automation technology;

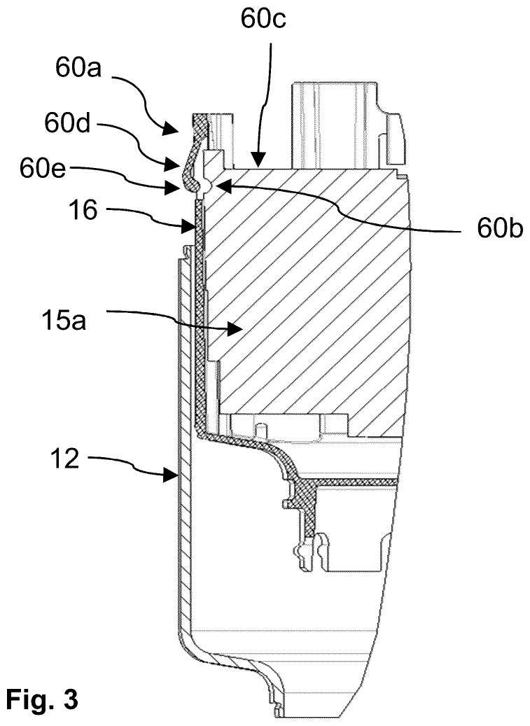

FIG. 3 a sectional view of a circuit board holder provided for use in a field device of automation technology, with, located therein, a circuit board to be retained in the circuit board holder by means of engagement and counter-engagement mechanisms, wherein, in the shown position, the engagement mechanism is not yet engaged in the counter-engagement mechanism (non-engaged state); and

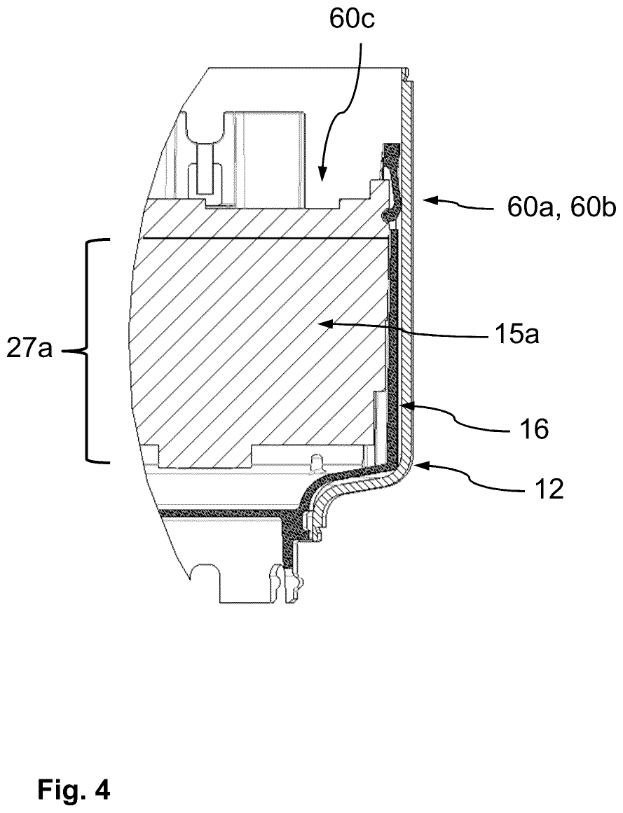

FIG. 4 a sectional view of a circuit board holder provided for use in a field device of automation technology, with, located therein, a circuit board, which is retained in the circuit board holder by means of the engagement and counter-engagement mechanisms (engaged state).

FIG. 1 shows a circuit board holder 16 known in the state of the art, such as usually currently applied in a field device 10 of automation technology. Circuit board holder 16 includes laterally placed guide rails 16a, which serve for receiving the circuit boards. Furthermore, circuit board holder 16 includes, such as already described above, a releasable engagement or fixing mechanism 16b in the lower region, via which a circuit board (not separately shown in FIG. 1) can be mechanically secured in the circuit board holder 16. The engagement or fixing mechanism 16b is, in such case, implemented in such a manner that two mutually opposing, elongated arms 16c are prepared from a side wall of the circuit board holder 16 during production, such that the arms 16c have a certain flexibility. On a circuit board holder central axis-facing side of each arm 16c, the circuit board holder 16 further includes a nose 16d, which engages a corresponding recess of an inserted circuit board.

This circuit board holder 16 was, until now, placed in the field device housing 12 and then filled with a potting compound 27. By placing the circuit board holder 16 in the housing 12, the “unsealed sites” (wall openings resulting from preparing the arms) were at least partially sealed by the tightly adjoining housing wall, such that the potting compound 27 remained in the circuit board holder 16. In order to prevent escape of 31 potting compound 27 into an inappropriate region of the field device housing 12, e.g., in the direction of an electronics unit arranged further below in the housing 12 and serving for processing and/or forwarding of signals produced by the sensor element 14, it can be necessary, in given cases, that further sealing measures be implemented.

FIG. 2 represents, by way of example, a sectional view of a field device 10 of automation technology. Field device 10 includes a field device housing 12, which surrounds an inner space 13. Field device housing 12 includes an at least sectionally rotationally symmetric subregion 17, in which is located a circuit board holder 16 to be described in greater detail below.

Furthermore, field device 10 includes: a sensor assembly arranged terminally in the field device housing 12 and having a sensor and/or actuator element 14 for setting and/or registering a process variable; and a process connection 28. Process connection 28 can be a screw thread type or a screwed or clampable flange.

The sensor and/or actuator element 14 in the present example of an embodiment comprises a fill level sensor element for registering a fill level as process variable. However, the invention is not limited to this type or particular embodiment of sensor and/or actuator element, but can, instead, be applied, in principle, to any kind of sensor or actuator.

Serving in the inner space 13 of the field device housing for providing and/or conditioning a sensor and/or actuator signal is a field device electronics unit 15. Field device electronics unit 15 thus operates the sensor and/or actuator element 14.

In the present example of an embodiment, the field device electronics unit includes three circuit boards 15a, 15b, 15c. These are connected electrically together via corresponding plug and counter-plug connectors 15d. These can be embodied both as rigid as well as also flexible connectors. Also, the positions of the plug and counter-plug connectors can be reversed.

Field device electronics unit 15 further includes a fourth circuit board 25 serving as an interface electronics unit 20 and having a field contact plug 21, which is arranged in a longitudinal axis of the circuit board 25 on a circuit board edge and soldered to such. Through field contact plug 21, data, especially measured values, and/or energy can be transferred between the field device 10 and an external unit, for example, a superordinated unit or other field device. Field contact plug 21 can especially be a plug/socket connector, for example, an M12-connector. In order to lead the field contact plug outwardly, the field device housing 12 includes a correspondingly formed housing opening 18. The fourth circuit board 25 can likewise be electrically connected with one of the other circuit boards via a plug and counter-plug connector 15e, 22. Furthermore, electronic components 24 for EMC and/or explosion protection measures can be applied on the circuit boards.

At an upper end of the field device 10, the field device housing 12 has a display 19 for display and/or interaction with the field device 10. The display can have capacitive keys for the interaction. Such can be implemented, for example, by a corresponding capacitive film. In order to meet hygienic requirements, the display can be arranged behind a viewing and touch screen 11 integrated in the housing 12 in the inner space 13 of the field device. In order to have a best possible view and readability of information on the display 19 placed behind the viewing screen 11 and/or a friction free operation of the capacitive keys, display 19 should contact the rear side of the viewing and touch screen 11 as planarly and/or uniformly as possible. Serving for this can be, for example, a display frame 30, which, on the one hand, receives the display, and, on the other hand, is placed correspondingly behind the viewing and touch screen 11.

Circuit boards 15a, 15b, 15c, 25 of the field device electronics unit 15 are arranged, at least partially, in a circuit board holder 16 and are mechanically secured by such. The circuit board holder is embodied with its outer contour in such a manner that it lies at least sectionally essentially flushly on an inner surface of the rotationally symmetric region of the housing.

In the example of an embodiment shown in FIG. 2, the circuit board holder 16 has a cup-like shape. For seating of the circuit boards, the circuit board holder 16 can have internal, lateral guide rails 16a, such also shown in FIG. 1. In such case, two, preferably diametrally oppositely arranged, guide rails 16a can be provided for receiving a circuit board. Furthermore, the circuit board holder 16 includes an engagement mechanism 60a for resistance capable securing of the circuit board 15a. Circuit board 15a includes for this, in turn, a corresponding counter-engagement mechanism 60b. For each circuit board to be installed in the circuit board holder, matching engagement and counter-engagement mechanisms are present. In the example of an embodiment shown in FIG. 2, the positions of the engagement and counter-engagement mechanisms are shown, by way of example, only by a box with the reference characters 60a, 60b. The engagement and counter-engagement mechanisms are arranged in the upper region of the circuit board holder and circuit board, i.e., on the end far from the sensor and/or actuator element 14. Thus, arranged in the circuit board holder, by way of example, is a circuit board 15a, which is retained releasably in the circuit board holder 16 by means of the engagement and counter-engagement mechanisms 60a, 60b. Circuit board 15a is potted in the circuit board holder 16 to a predetermined potting compound height 27a by means of potting compound 27. Serving as potting compound can be, for example, SILGel silicone gel. Usually, the potting compound height 27a is determined in such a manner that the potting compound fills about half to two thirds of the volume of the circuit board holder 16. The engagement and counter-engagement mechanisms 60a, 60b are then arranged in the non-potted region of the circuit board holder 16 and the circuit board 15a. Preferably, the circuit board holder (16) is formed in such a manner that it has up to the predetermined potting compound height 27a no opening in the outer contour, such that when being potted with the potting compound such cannot leak from the circuit board holder. Furthermore, the circuit boards 15b and 15c are potted in the circuit board holder with the potting compound 27.

The potting can, in such case, be done before the installation of the circuit board holder in the field device housing, such that the circuit board holder with the circuit board located therein can be manufactured as a preassembled module. Alternatively, the circuit board holder can, however, also be potted with the potting compound after installation in the field device housing.

For a more detailed description of the engagement and counter-engagement mechanisms 60a, 60b, FIG. 3 shows, by way of example, a sectional view of a circuit board holder 16 provided for use in an automation field device 10 and having located therein a circuit board 15a, which is to be held in the circuit board holder 16 by means of the engagement and counter-engagement mechanisms 60a, 60b. FIG. 3 shows the non-engaged state, in the case of which the circuit board holder 16, at least with the subregion, is not completely installed in the field device housing 12 and the engagement and counter-engagement mechanisms 60a, 60b are not yet engaged with one another. FIG. 4 shows, in contrast, the engaged state, in the case of which the circuit board holder 16, at least with the subregion, is installed in the field device housing 12 and the engagement and counter-engagement mechanisms 60a, 60b are engaged with one another.

As evident from FIG. 3, the engagement mechanism 60a is embodied in the form of a latch formed from the wall, or provided in the wall, and the counter-engagement mechanism 60b of the at least one circuit board 15a is embodied in the form of a recess, in which the latch can engage in the engaged state. The engagement mechanism 60a can be manufactured, for example, along with the production of the circuit board holder 16, e.g., by means of a corresponding injection molding method. The counter-engagement mechanism 60b can be formed, for example, by milling a corresponding outer contour of the circuit board 15a.

The latch 60a comprises, in turn, a flexible, elongated arm 60d connected on one end with the wall of the circuit board holder 16 and an engagement catch 60e arranged on the other end of the elongated arm. The latch 60a is, in such case, so embodied that, in the non-engaged state shown in FIG. 3, it protrudes outwards from the outer contour of the wall of the circuit board holder 16. Especially, latch 60a is so embodied that the engagement catch 60e of the latch in this state is outside of the outer contour, such that the engagement catch 60e still does not engage in the counter-engagement mechanism 60b of the already installed circuit board 15a. Starting from this state, the flexible latch 60a can be brought into the engaged state by introducing the circuit board holder 16 completely into the field device housing 12. In such case, the latch 60a is pressed inwardly (i.e., in the direction of the at least one circuit board 15a) by the inner contour of the field device housing closely adjoining the outer contour of the circuit board holder 16, such that the engagement catch 60e engages in a corresponding recess serving as counter-engagement mechanism 60b of the circuit board. This is shown in FIG. 4.

In the examples of embodiments illustrated in FIGS. 3 and 4, in each case, only one pair of engagement and counter-engagement mechanisms 60a, 60b is shown. Actually, both the circuit board holder 16 as well as also the circuit board 15a can have a plurality of engagement and counter-engagement mechanisms 60a, 60b. Especially, the shown circuit board holder 16 can have two engagement mechanisms 60a per circuit board 15a, 15b, which are preferably arranged diametrally opposite one another. The circuit board 15a can correspondingly have two counter-engagement mechanisms 60b, which are located at a trailing circuit board edge 60c of the installed circuit board. Furthermore, also a plurality of circuit boards 15a, 15b can be held in the circuit board holder by correspondingly embodied engagement and counter-engagement mechanisms 60a, 60b.

### LIST OF REFERENCE CHARACTERS

10 field device of automation technology
11 viewing screen
12 field device housing
13 inner space
14 sensor and/or actuator element
15 field device electronics unit
15a-15c circuit boards
15d plug and counterplug connector
15e plug connector
16 circuit board holder
16a lateral guide rails of the circuit board holder
16b engagement or fixing mechanism according to the state of the art
16c arm of the circuit board holder according to the state of the art
16d nose of the circuit board holder according to the state of the art
17 rotation symmetric subregion
18 housing opening
19 display
20 interface electronics unit
21 field contact plug
22 counterplug connector of the interface electronics
24 electronic components, for example, for EMC and/or Ex-protective measures
25 other circuit board
26 plug conduit for field contact plug
27 potting compound
27a predeermined potting compound height, up to which the circuit board is potted in the circuit board holder with the potting compound
28 process connection
30 display frame
40 display holder
50 support plate, or circuit board
60a engagement mechanism of the circuit board holder, especially latch
60b counter-engagement mechanism of the circuit board, especially recess
60c circuit board edge where the engagement mechanism is formed
60d flexible arm of the latch
60e engagement catch of the latch

1-10. (canceled)

11. An automation field device, comprising:
a field device housing;
a field device electronics unit including at least one circuit board and arranged in the field device housing;
a circuit board holder arranged in the field device housing and configured to hold the at least one circuit board, wherein the circuit board holder, having a peripheral outer contour of a wall, is fitted, at least in a subregion, to an inner contour of the field device housing such that the outer contour of the circuit board holder lies essentially flushly against the inner contour of the field device housing,
wherein the circuit board holder includes, in the subregion, at least one engagement mechanism configured to secure the at least one circuit board,
wherein the at least one circuit board includes at least one counter-engagement mechanism corresponding to an engagement mechanism of the least one engagement mechanism of the circuit board holder,
wherein the corresponding engagement mechanism is configured as a latch formed from the wall or provided in the wall, wherein the latch is flexibly embodied such that, in a non-engaged state, the latch extends beyond the outer contour of the wall, and, in an engaged state, the latch is displaced toward the at least one circuit board so as to be engaged with the counter-engagement mechanism,
wherein, in the non-engaged state, the circuit board holder, at least with the subregion, is not completely installed in the field device housing, and, in the engaged state, the circuit board holder, at least with the subregion, is installed in the field device housing,
wherein the at least one circuit board is installed in the circuit board holder and the circuit board holder, at least with the subregion, is installed in the field device housing, such that the corresponding engagement and the counter-engagement mechanisms are engaged with each other, and the circuit board holder holds the at least one circuit board,
wherein the at least one circuit board is potted in the circuit board holder with a potting compound to a predetermined potting compound height,
wherein the corresponding engagement and counter-engagement mechanisms are configured in, or on, the circuit board holder and the at least one circuit board, respectively, such that the corresponding engagement and counter-engagement mechanisms lie above the potting compound height and thereby are not potted.

12. The field device as claimed in claim 11, wherein the latch comprises:
an elongated arm formed from the wall of the circuit board holder; and
an engagement catch disposed at an end of the elongated arm.

13. The field device as claimed in claim 11, wherein the at least one circuit board includes at least one recess, in which the latch can engage in the engaged state.

14. The field device as claimed in claim 11, wherein the circuit board holder includes at least two engagement mechanisms for securing the at least one circuit board, and the at least one circuit board includes at least two counter-engagement mechanisms corresponding to the at least two engagement mechanisms of the circuit board holder.

15. The field device as claimed in claim 14, wherein the at least two engagement mechanisms of the circuit board holder are arranged diametrally opposite each other and the at least two counter-engagement mechanisms of the at least one circuit board are formed diametrally opposite each other on a circuit board edge of the at least one circuit board, wherein the circuit board edge is a trailing end of the circuit board as installed in the circuit board holder.

16. The field device as claimed in claim 11, wherein the circuit board holder has a cup-like form.

17. The field device as claimed in claim 11, wherein the circuit board holder is embodied such that it has no opening in the outer contour within the predetermined potting compound height.

18. A method for manufacturing a process automation field device as claimed in claim 11, the method comprising:
providing the field device housing, the field device electronics unit including the at least one circuit board, and the circuit board holder configured to hold the at least one circuit board;
introducing the at least one circuit board in the circuit board holder in the non-engaged state, in which the circuit board holder, at least with the subregion, is not yet installed in the field device housing; and
installing the circuit board holder, at least with the subregion, in the field device housing such that the latch moves toward the at least one circuit board and engages the counter engagement mechanism in the engaged state.

19. The method as claimed in claim 18, wherein the at least one circuit board is potted in the circuit board holder with the potting compound to the predetermined potting compound height, before the circuit board holder is installed in the field device housing.

20. The method as claimed in claim 18, wherein the at least one circuit board in the circuit board holder is potted in the circuit board holder with the potting compound to the predetermined potting compound height, after the circuit board holder is installed in the field device housing.
